(19) United States
(12) Patent Application Publication
(10) Pub. No.: US 2006/0156141 A1
(43) Pub. Date: Jul. 13, 2006

(54) Defect symptom repair system and methods

(76) Inventor: Norman Ken Ouchi, San Jose, CA (US)

Correspondence Address: NORMAN KEN OUCHI, P.O. BOX 20111, SAN JOSE, CA, 95160, US

(21) Appl. No.: 11/007,716

(22) Filed: Dec. 7, 2004

(51) Int. Cl. G01R 31/28; G06F 11/00

(52) U.S. Cl. 714/742

(57) ABSTRACT

The present invention is related to the repair of defective items where the defect symptom does not readily suggest the action to repair the item. Test and repair technicians isolate and repair defects. The defect symptom repair system provides a means for the technicians to pool their experience without extensive effort and to make their experience readily available. The defect symptom repair system is implemented as a web server on the Internet and easily accessible with use of web enabled devices. A defect symptom repair web server provides defect symptoms and associated repair actions. Each repair action has an effectiveness indicator. The defect symptom is match with the observed symptom. A repair action associated with the defect symptom is selected based on the effectiveness indicator. The repair action is applied to the item. The result, success or failure, is entered into the defect symptom repair web server and the effectiveness indicator of the repair action is computed including the most recent result. If the observed symptom does not match a defect symptom from the server, a defect symptom is created in the server. If a new repair action for a defect symptom is attempted, a repair action is added and the effectiveness indicator is calculated based on the result of the repair action attempt.

### CROSS-REFERENCE TO RELATED APPLICATIONS

None

### STATEMENT REGARDING FEDERALLY SPONSORED RESEARCH OR DEVELOPMENT

None

### FIELD OF THE INVENTION

The present invention is related to the repair of defective items where the defect symptom does not readily suggest the action to repair the item

### BRIEF SUMMARY OF THE INVENTION

Test and repair technicians isolate and repair defects. The defect symptom repair system provides a means for the technicians to pool their experience without extensive effort and to make their experience readily available. The defect symptom repair system is implemented as a web server on the Internet and accessible with web enabled devices. A defect symptom repair web server provides defect symptoms and associated repair actions. Each repair action has an effectiveness indicator. The defect symptom is match with the observed symptom. A repair action associated with the defect symptom is selected based on the effectiveness indicator. The repair action is applied to the item. The result, success or failure, is entered into the defect symptom repair web server and the effectiveness indicator of the repair action is computed including the most recent result. If the observed symptom does not match a defect symptom from the server, a defect symptom is created in the server. If a new repair action for a defect symptom is attempted, a repair action is added and the effectiveness indicator is calculated based on the result of the repair action attempt.

### BACKGROUND OF THE INVENTION

Defects cause products to fail. If the defect is repaired, an item may be usable again. Many systems and methods are developed for defect identification and repair of the defect. In some cases the repairable defect may not be obvious. Expert systems with decision trees, rule based systems, knowledge base systems, and neural networks have been developed to determine the defect when presented with a symptom. Systems have been developed to “capture” the experience of experts so that the resultant system can provide guidance of the expert in the system. Other systems provide means to modify the “experience” base so that experience from use of the system can be captured.

Defect identification systems require significant development and overhead to maintain. Many require an “expert” to aid in the development of the decision tree or knowledge base.

Hence, defect isolation systems have been limited to high value items where the investment makes economic sense. Also, many defect isolation systems are developed for use on items that have completed the manufacturing process and in use. The number and types of defects found in an item that was manufactured correctly is much smaller than those found in an item that was never “correct”. Tests in the manufacturing process focus on assuring that the manufacturing process is functioning properly and usually does not test the function of the item. In some complex products, the item is tested to assure proper function. “Functional test” is for some items, a comprehensive test of the function of the item. For electronic products, a defect at functional test is usually the most difficult to isolate and repair. Many electronic products are no longer manufactured on dedicated lines of the company who's logo appears on the product but rather on assembly lines of contract manufacturers that build products on behalf of many companies, even companies that compete with one another. The test and repair technicians of the contract manufacturer are skilled but may not have extensive experience with each of the hundreds of different items they must test and repair. The test technicians detect the defect and describe the symptoms for the repair technician to repair. If the test technician does not describe the symptom consistently and accurately, the task for the repair technician is more difficult. The company that contracted the manufacture of the item may not have the engineering experience with the item since the design of the item may have been contracted to a third party. Hence, the test and repair technicians of the contract manufacturer are on their own. No one will develop an expert system to isolate defects in manufacturing. No one can afford the delay in time and the expense to develop a system to aid in defect isolation for all of these products.

In many cases, each technician discovers the relationship between the symptom for a defect and the repair of the defect. Many of the defects found in manufacturing are not normally found in standard use of the item. Most defects are due to problems in the manufacture of the item. For example, inaccurate assembly instructions, bad batch of components, shift changes, assembly employees that lack training, etc. may be the source of the defect. The defect is observed when failing a test. This is the defect symptom. In a manufacturing process, the repair of the defect is done in two steps: 1) repair the item 2) fix the manufacturing process to avoid repeating the problem. Because the defect sources are process related, the defect rate has two characteristics: 1) defect comes in bursts where the same manufacturing problem is in many items; 2) the problem may reappear when the “fix” to the process is forgotten.

By the nature of the business, a contract manufacturer has additional problems in capturing and retaining this knowledge. The contract manufacturer assembles many different items for many customer companies. The test and repair technicians are not dedicated to a product. The items may come in batches where there may be time between batches. The experience is forgotten between batches. The early pilot units may be manufactured at a first site and subsequent volume production may be at a second site. In fact volume production may be at multiple geographically dispersed sites. The test and repair technicians are under time pressure to deliver products. They do not have the time to develop expert systems or knowledge bases. The contract manufacturer has very narrow margins and cannot afford to dedicate resources to develop expert systems.

The test and repair technicians would benefit from their shared knowledge to isolate defects and repair items quickly and accurately. The technicians do not have time to enter information on their experience or time to learn a complex interface to find the information they need when isolating a defect. The defect symptom and repair action information must be both gathered and applied globally.

### BRIEF DESCRIPTION OF DRAWINGS

FIG. 1 illustrates the Defect Symptom Repair Server and an item tested to uncover a defect, the defect symptom is matched, the repair action with an effectiveness indicator is selected, and the result of the repair action is entered in the server.

### DESCRIPTION OF THE INVENTION

The defect symptom and repair system provides a defect symptom and one or more related repair actions. The defect symptom describes the defect. The test technician selects a defect symptom that best describes what is observed. If a suitable symptom description cannot be found, the technician adds a defect symptom. The technician can edit a description to improve the accuracy of the description. The system provides a consistent description of the defect rather than a text note written by the test technician. The organization may have a quality system to track the type and number of defects. The defect symptom may be assigned a quality code and tracked in the quality system.

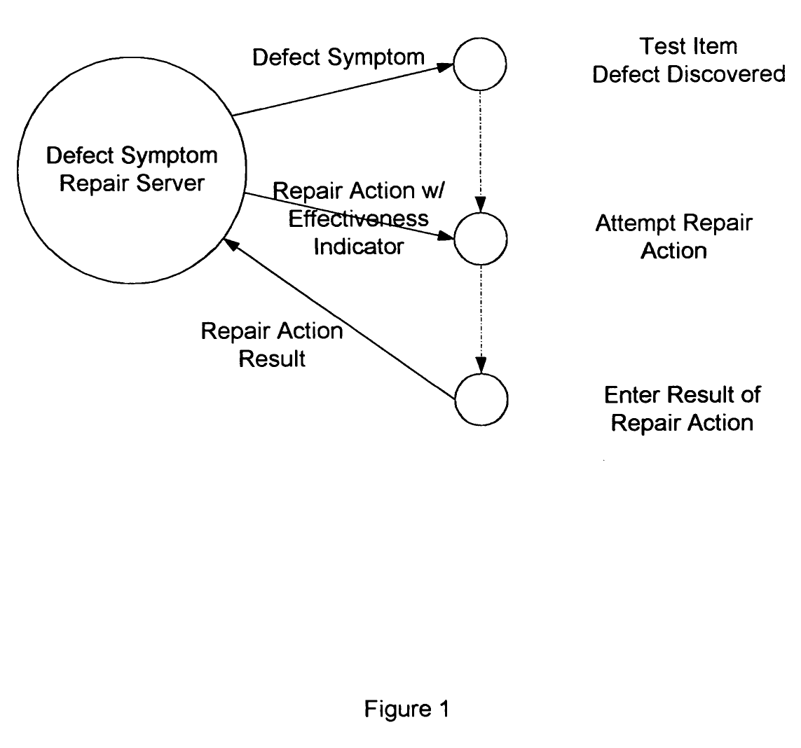

The repair technicians are experienced and have skills to isolate many of the defects. However, some defects have symptoms where the defect is not apparent or misleading. The repair action describes an attempt to repair the defect and an indicator of the effectiveness of the repair action as experienced by repair technicians. The repair actions include attempts that fail. Knowledge of what does not work may be as important as knowing what works. Some repair actions fix the defect but lower cost solutions are later found. The repair action effectiveness indicator may have several components and may be simple to calculate. Examples of indicators are percentage of success, number of usages, most recent usage, average time to fix, average cost of fix. The percentage of success is the percentage of successful fixes divided by the total attempts to fix using the repair action. A zero or low percentage is an indicator that the repair action is probably not one that the repair technician would want to try. The number of usages is an indicator of how many times the repair action was attempted. If the success percentage is high, the repair technician may want to use the most popular repair action. The most recent usage provides a means to move from one repair action that was successful to another that is also successful but having other benefits such as lower cost. A repair technician may choose from two repair successful actions the one with the most recent date since the repair action has become the new way to fix the defect. The average time to fix and average cost to fix also indicate the effectiveness of a repair action. Given a choice, the repair technician would choose lower cost or perhaps discover a lower cost repair action. An overview of the process is illustrated in FIG. 1 where an item is tested or fails and a defect is discovered. The test technician selects a defect symptom with a description matching the observed symptoms. The item identifier is related to defect symptom so the repair technician can access the repair actions. Associated with defect symptom are one or more repair actions each with indicators of effectiveness. The repair technician selects a repair action and applies it to the item. The result of the repair action is fed back to compute the effectiveness indicator including the result.

The system is implemented as a web site that uses the Internet. The clients are web-enabled devices with browsers. The test technician tests the item and uncovers a defect. The technician uses the web-enabled device to select the defect symptom that best describes the observed symptom. If one is not found, the technician enters a new symptom. The defect symptom is associated with the item. The item may have a barcode or other identifier to select the item. If there is a quality tracking system, the defect symptom is entered into the quality tracking system. The item is sent to the repair technician. In some cases the test technician and repair technician are the same person and the defect detection and repair may be done as one operation in a manufacturing process.

The repair technician receives the item, selects the item identifier and accesses the associated defect symptom. The defect symptom may have one or more repair actions each with an effectiveness indicator. The repair technician selects a repair action that appears to be the most effective. A high success rate, high usage, most recent use, and low costs would be the most preferable. The repair actions listing may also show repair actions with zero success. These are failed attempts to fix the defect. Knowledge of what not to do is as valuable as what to try. If the technician does not find a repair action that appears to be suitable, a new repair action may be entered by the technician. A repair action is selected and the repair attempted. The technician enters the result of the repair action: success or failure and, if required, the time and cost. The system calculates the effectiveness indicator based on the added information. If the repair action was successful, the code for the repair is made in the quality tracking system. The quality tracking system is used to get to the root cause. This may result in a change in the manufacturing process, component sourcing, etc. to solve the real problem since most manufacturing problems are due to the process or component quality and not failures as seen in the field once the item is shipped and in use.

The user interface is similar to web services and familiar to most technicians. To minimize data entry and to focus the defect symptom and repair action information, the entries are associated with the part number of the item. A set of similar products may have identical defect symptoms and repair actions. These are grouped as a “part number family” and share the same defect symptom and repair action information. The test technician selects the defect symptom from a list. Clicking a button on the screen provides a detailed description of the symptom. If an appropriate defect symptom cannot be found, the test technician clicks a button to display a defect symptom entry screen. The repair technician sees a similar set of screens to display the repair actions related to the defect symptom. Each repair action has an indicator of effectiveness. The interface is similar many web sites, for example, a book sales web site where users can enter a book review, other users read the review and “grade” the review so that subsequent users can select reviews with good grades to read and ignore the others. In the defect symptom and repair system, the “grade” is calculated by the success or failure of the repair action and other information entered by the repair technician.

The defect symptom repair system provides
1. for the test technician a consistent and accurate description of the defect symptom
2. for the repair technician, the description of the defect symptom and the repair actions, each with an indicator of effectiveness to repair the defect.
3. the information is related to a product or product family to focus the access to information
4. the information is accessible globally and in real time
5. the defect and repair action may be recorded in a quality tracking system.
6. the defect symptom and repair action information is the shared pool of experience of the technicians. Engineers and others may add to the information.
7. use is not limited to the manufacturing process; can be used for products in use and for problems encountered in other business processes.

### DESCRIPTION OF A PREFERRED EMBODIMENT

The defect symptom and repair system is implemented as web site and database. The web site provides the interface to information in the database. Each item tested has an identifier such as a barcode. A database table relates the item barcode to the part number of the item. A set of part numbers called a part number family have identical defect symptom descriptions and repair actions. A second database table relates the part number to a part number family. A third database table relates a part number family to defect symptoms. A fourth database table relates defect symptoms to repair actions. A fifth database table relates an item barcode to a defect symptom.

The third table that relates a part number family to defect symptoms is illustrated in Table 1. As an example, for part family PNF123, a defect symptom of “Loss Synch” is described

TABLE 1
Part Number Family to Defect Symptoms Table

| Part Number Family | D.S. ID | Title | Description |
|---|---|---|---|
| PNF123 | ID 5 | Loss Synch | Loss Synch at |
| | | | low voltage |

The fourth table that relates a defect symptom to repair actions is illustrated in Table 2. Repair actions for the “Loss Synch” defect symptom description is illustrated.

TABLE 2
Defect Symptom to Repair Action Table

| | | | # | | | |
|---|---|---|---|---|---|---|
| D.S. | | Descrip- | Times | % | Date last | Time to |
| ID | Title | tion | Used | Success | used | Repair |
| ID 5 | Change | Change | 32 | 100 | Aug. 4, 2004 | 10 min |
| | Input 3 | input | | | | |
| | | module 3 | | | | |
| ID 5 | Adjust | Adjust | 5 | 100 | Dec. 5, 2004 | 2 min |
| | Input 3 | input | | | | |
| | | module 3 | | | | |
| ID 5 | Change | Change | 1 | 0 | Jun. 3, 2004 | 10 min |
| | connec- | connector | | | | |
| | tor 7 | to input | | | | |
| | | module 3 | | | | |

For the example, a test technician is testing an item in the part number family PNF123 where the item has barcode BC12345. The test technician tests the item and detects a loss of synchronization while testing at low voltage. The technician reads the barcode BC12345. The system relates the barcode BC12345 to the part number family PNF123 using the first table and second table. The system displays the defect symptoms for PNF123 using the third table illustrated as Table 1. The test technician selects the Loss Synch title and the system displays the description. The test technician selects the defect symptom as the description of the defect and the system associates the item barcode with the defect symptom.

The repair technician reads the barcode BC12345 on the item and the system returns the defect description and three repair actions Change Input 3, Adjust Input 3 and Change connector 7. The repair technician observes that Change Input 3 and Adjust Input 3 have been used with 100% success and that Change Connector 7 has 0% success. Changing connector 7 is not a good choice. Change Input 3 has been used 32 times and Adjust Input 3 only 5 times. However, the Time to Repair shows that the time to change input 3 is longer than the time to adjust input 3 and that the most recent use was adjust input 3. The test technician chooses to adjust input 3. The defect disappears after the adjustment. The technician enters the fact that the repair action fixed the problem and that it took 3 minutes. The system changes the times used to 6 and calculates the new average time to 2.16 min.

The next repair technician that encounters the Loss of Synch defect will see the updated information.

The web page for the test technician provides for adding another defect symptom or editing an existing defect symptom description. The web page for the repair technician provides for adding another repair action or editing an existing repair action.

The web site may be implemented using Microsoft Web server, IBM Websphere, or other commercial web server system. The programs may be written in Java, C++, Microsoft Visual Basic, Microsoft Active Server Pages, Microsoft Net, BEA J2EE or a number of programming languages. The programs may use a database for storing translation tables and other information. Database programs are available from Oracle, IBM, Microsoft, and many other providers. The web server and programs and databases execute in computers manufactured by, for example, IBM, Sun, Dell, and Compaq. The computers may be, for example, PC's, workstations, mainframes, and hand-held computers. The computers may have an operating system such as UNIX, LINUX, Microsoft 2000, and IBM OS/9000. The computer is connected to a network that may be, for example, a LAN, WAN, Internet, Intranet, wireless LAN, or wireless Internet.

I claim:

1. A defect symptom repair system comprising
a defect symptom repair server;
a client terminal, both connected by a network;
a defective item with a defect symptom; where
the client terminal presents a first defect symptom description
the first defect symptom is matched with the defect symptom of the defective item
the client terminal presents an associated first repair action with a measure of effectiveness;
the first repair action is applied to the defective item;
the result, success or failure, of the first repair action to repair the defective item is entered at the client terminal;
the measure of effectiveness of the first repair action is computed to reflect the results of the application of the first repair action and updated in the defect symptom repair server.

2. The defect symptom repair system of claim 1, wherein a second defect symptom description is added to the defect symptom repair server

3. The defect symptom repair system of claim 1, wherein a second repair action with a measure of effectiveness of the second repair action is associated with the first defect symptom description and added to the defect symptom repair server

4. The defect symptom repair system of claim 1, wherein the first defect symptom description may be edited

5. The defect symptom repair system of claim 1, wherein the first repair action may be edited.

6. The defect symptom repair system of claim 1, wherein the network is the Internet and the client terminal is an Internet enabled device.

7. The defect symptom repair system of claim 1, wherein the first repair action effectiveness includes percent successful, number of times applied, date of most recent application.

8. The defect symptom repair system of claim 1 and a quality data collection system, wherein a first defect symptom datum is entered in the quality data collection system when the first defect symptom is selected.

9. The defect symptom repair system of claim 1 and a quality data collection system, wherein a first repair action datum is entered in the quality data collection system when the first repair action corrects the defect.

10. The defect symptom repair system of claim 1 and a part number family (a set of part numbers that have identical defect symptom descriptions and repair actions including the first defect symptom and first repair action) wherein part number family is related to the first defect symptom.

11. A method of repairing a defective item comprising
a defect symptom repair action database including
a first defect symptom description entry and
an associated first repair action with a measure of effectiveness entry
a means to access entries in the defect symptom repair action database
a defective item with a defect symptom where
the item defect symptom is matched with the first defect symptom
the first repair action is applied to the defective item
the effectiveness of the first repair action is computed including the success or failure of the first repair action to repair the defective item and updated in the database.

12. The method of repairing a defective item of claim 11, wherein a second defect symptom description entry is added to the defect symptom repair action database.

13. The method of repairing a defective item of claim 11, wherein a second repair action associated with the first defect symptom and a measure of effectiveness entry is added to the defect symptom repair action database.

14. The method of repairing a defective item of claim 11, wherein the network is the Internet and the means to access entries in the defect symptom repair action database is a web enabled device.

15. The method of repairing a defective item of claim 11 and a means to collect defect information, wherein information related to the first defect symptom is collected when the first defect symptom is selected and information related to the first repair action is collected after the first repair action is applied.

16. A defect symptom repair database,
a client terminal, both connected by a network,
a defective item with a defect symptom where the defect symptom repair database includes
a first defect symptom description and
an associated first repair action with an effectiveness indicator wherein
a. the client terminal displays the first defect symptom description
b. the first defect symptom is matched with the defect symptom of the item
c. the client terminal displays the first repair action with the effectiveness indicator
d. the first repair action is applied to the defective item
e. the effectiveness indicator for the first repair action is calculated including the result of applying the first repair action to the defective item and updated in the database.

17. The defect symptom repair database of claim 16, wherein a second defect symptom description is added to the defect symptom repair database.

18. The defect symptom repair database of claim 16, wherein a second repair action associated with the first defect symptom and an effectiveness indicator is added to the defect symptom repair database.

19. The defect symptom repair database of claim 16, wherein the network is the Internet and the client terminal is a web enabled device with a web browser.
